(19) United States
(12) Patent Application Publication
(10) Pub. No.: US 2026/0362922 A1
(43) Pub. Date: Nov. 12, 2026

(54) DISPLAY MODULE, METAL PLATE, AND ELECTRONIC DEVICE

(71) Applicant: Samsung Display Co., LTD., Yongin-si (KR)

(72) Inventors: DAEGUEN CHOI, Yongin-si (KR); BOO-KAN KI, Yongin-si (KR); JIHOON KIM, Yongin-si (KR); CHEOLGEUN AN, Yongin-si (KR)

(21) Appl. No.: 19/539,317

(22) Filed: Feb. 13, 2026

(30) Foreign Application Priority Data
May 8, 2025 (KR) 10-2025-0060034
Aug. 1, 2025 (KR) 10-2025-0105727

(51) Int. Cl. H10K 59/131

(52) U.S. Cl. CPC H10K 59/131

(57) ABSTRACT

A display module includes: a display panel including a deformation area capable of sliding or bending and a non-deformation area adjacent to the deformation area, and including a plurality of pixels, a support plate disposed under the display panel and defining a plurality of openings overlapping the deformation area and the non- deformation area in a plan view, and a protective film disposed on the support plate and defining a plurality of trenches recessed from a first surface of the protective film, which faces the support plate, toward a second surface of the protective film, which is opposite the first surface, where each of the plurality of trenches overlaps at least one of the plurality of openings in the plan view.

### CROSS-REFERENCE TO RELATED APPLICATIONS

This application claims priority to Korean Patent Application No. 10-2025-0060034, filed on May 8, 2025 and Korean Patent Application No. 10-2025-0105727, filed on Aug. 1, 2025, and all the benefits accruing therefrom under 35 U.S.C. §119, the contents of which in their entirety are herein incorporated by reference.

### BACKGROUND

### 1. Technical Field

Embodiments provide generally to a display module, a metal plate included therein, and an electronic device manufactured using the same.

### 2. Description of the Related Art

An electronic device may include a flexible display panel and may have various shapes, such as being curved, foldable, or rollable. A flexible electronic device capable of varying shapes may be easily carried and offer enhanced user convenience.

The electronic device may be manufactured from a display module which includes a display panel on which an image is displayed and a protective film disposed under the display panel. For example, the electronic device may be manufactured by removing the protective film from the display module and assembling the display module with various sets.

### SUMMARY

Embodiments provide a display module with improved reliability.

Embodiments provide a metal plate included in the display module.

Embodiments provide an electronic device manufactured using the display module.

A display module according to an embodiment of the present disclosure includes a display panel including a deformation area capable of sliding or bending and a non-deformation area adjacent to the deformation area, and including a plurality of pixels, a support plate disposed under the display panel and defining a plurality of openings overlapping the deformation area and the non- deformation area in a plan view, and a protective film disposed on the support plate and defining a plurality of trenches recessed from a first surface of the protective film, which faces the support plate, toward a second surface of the protective film, which is opposite the first surface, where each of the plurality of trenches overlaps at least one of the plurality of openings in the plan view.

In an embodiment, each of the plurality of trenches may be spatially connected to and overlap at least one of the plurality of openings in the plan view.

In an embodiment, each of the plurality of trenches may extend in a first direction and each of the plurality of openings may extend in a second direction intersecting the first direction.

In an embodiment, the protective film may include a first protective film and a second protective film, and the second protective film may be disposed between the first protective film and the support plate.

In an embodiment, the first protective film may include a first base layer and a first adhesive layer disposed on the first base layer, and the second protective film may include a second base layer and a second adhesive layer disposed on the second base layer.

In an embodiment, the first protective film and the second protective film may include the same material.

In an embodiment, the second protective film may include a plurality of patterns spaced apart from each other, the plurality of patterns may define the plurality of trenches, and the plurality of patterns and the plurality of trenches may be alternately arranged along the second direction.

In an embodiment, a first thickness of the first protective film and a second thickness of the second protective film may be the same.

In an embodiment, a first width of each of the plurality of patterns in a direction in which each of the plurality of openings extends may be greater than or equal to a second width of each of the plurality of trenches in the direction.

In an embodiment, the plurality of trenches may overlap the deformation area and the non-deformation area in the plan view.

In an embodiment, the protective film may be disposed under the support plate.

In an embodiment, wherein the protective film may be disposed between the display panel and the support plate.

A metal plate according to an embodiment of the present disclosure includes: a support plate defining a plurality of openings across a whole surface thereof in a plan view and defining a plurality of trenches recessed from a first surface toward a second surface opposite the first surface, where each of the plurality of trenches is spatially connected to at least one of the plurality of openings; and a protective film disposed on the support plate.

In an embodiment, the support plate may include first patterns and second patterns which are connected to each other, and a thickness of each of the first patterns may be different from a thickness of each of the second patterns.

In an embodiment, the support plate may further include a barrier layer disposed on the support plate. The support plate may be disposed between the protective film and the barrier layer, the first patterns may contact the barrier layer and the protective film, and the second patterns may contact the barrier layer, be spaced apart from the protective film, and define the plurality of trenches.

In an embodiment, the first patterns may be arranged in a first direction, and the second patterns may be arranged in the first direction.

In an embodiment, the first patterns and the second patterns may be alternately arranged along a second direction intersecting the first direction.

In an embodiment, the plurality of trenches may be defined across the whole surface of the support plate.

An electronic device according to an embodiment of the present disclosure includes a display device including a plurality of pixels and a processor which provides a control signal and an input image data to the display device. The display device includes: a display panel including a deformation area capable of sliding or bending and a non-deformation area adjacent to the deformation area, and including a plurality of pixels and a support plate disposed under the display panel and defining a plurality of openings overlapping the deformation area and the non- deformation area in a plan view. The electronic device is manufactured by removing a protective film from the display module including: the display panel, the support plate, and the protective film disposed on the support plate and defining a plurality of trenches recessed from a first surface toward a second surface opposite the first surface, each of the plurality of trenches overlapping at least one of the plurality of openings in the plan view.

An electronic device according to an embodiment of the present disclosure includes a display device including a plurality of pixels and a processor which provides a control signal and an input image data to the display device. The display device includes: a display panel including a deformation area capable of sliding or bending and a non-deformation area adjacent to the deformation area, and including a plurality of pixels and a support plate disposed under the display panel and defining a plurality of openings overlapping the deformation area and the non- deformation area in a plan view, where the electronic device is manufactured by removing a protective film from a display module including: the display panel, the support plate, and the protective film disposed on the support plate and defining a plurality of trenches recessed from a first surface of the protective film, which faces the support plate, toward a second surface of the protective film, which is opposite the first surface, and where each of the plurality of trenches overlaps at least one of the plurality of openings in the plan view.

A display module according to embodiments of the present disclosure may include a display panel and a metal plate disposed under the display panel. The metal plate may include a support plate defined openings, and trenches may be defined in the metal plate to connect the openings to an outside. Accordingly, air may flow into the openings, so that even if the external air pressure changes, the air pressure within the openings may change correspondingly, and the occurrence of defects such as bubbles within the display module and deformation of the display panel may be effectively prevented or minimized.

### BRIEF DESCRIPTION OF THE DRAWINGS

Illustrative, non-limiting embodiments will be more clearly understood from the following detailed description in conjunction with the accompanying drawings.

FIGS. 1 and 2 are perspective views illustrating a display device according to an embodiment.

FIGS. 3 and 4 are perspective views illustrating a display panel included in the display device of FIGS. 1 and 2.

FIG. 5 is a cross-sectional view illustrating a display module according to an embodiment.

FIG. 6 is a plan view illustrating a portion of a metal plate included in the display module of FIG. 5.

FIG. 7 is a cross-sectional view taken along line I-I’ of FIG. 6.

FIG. 8 is a cross-sectional view illustrating a state in which a metal plate included in the display module of FIG. 5 is provided.

FIG. 9 is a cross-sectional view illustrating a display module according to another embodiment.

FIG. 10 is a plan view illustrating a portion of a metal plate included in the display module of FIG. 9.

FIG. 11 is a cross-sectional view taken along line II-II’ of FIG. 10.

FIG. 12 is a cross-sectional view illustrating a display module according to still another embodiment.

FIG. 13 is a plan view illustrating a portion of a metal plate included in the display module of FIG. 12.

FIG. 14 is a cross-sectional view taken along line III-III’ of FIG. 13.

FIG. 15 is a block diagram illustrating an electronic device according to an embodiment.

FIG. 16 is a schematic diagram illustrating electronic devices according to embodiments.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments of the present disclosure will be explained in detail with reference to the accompanying drawings. The same reference numerals are used for the same components in the drawings, and redundant descriptions of the same components will be omitted.

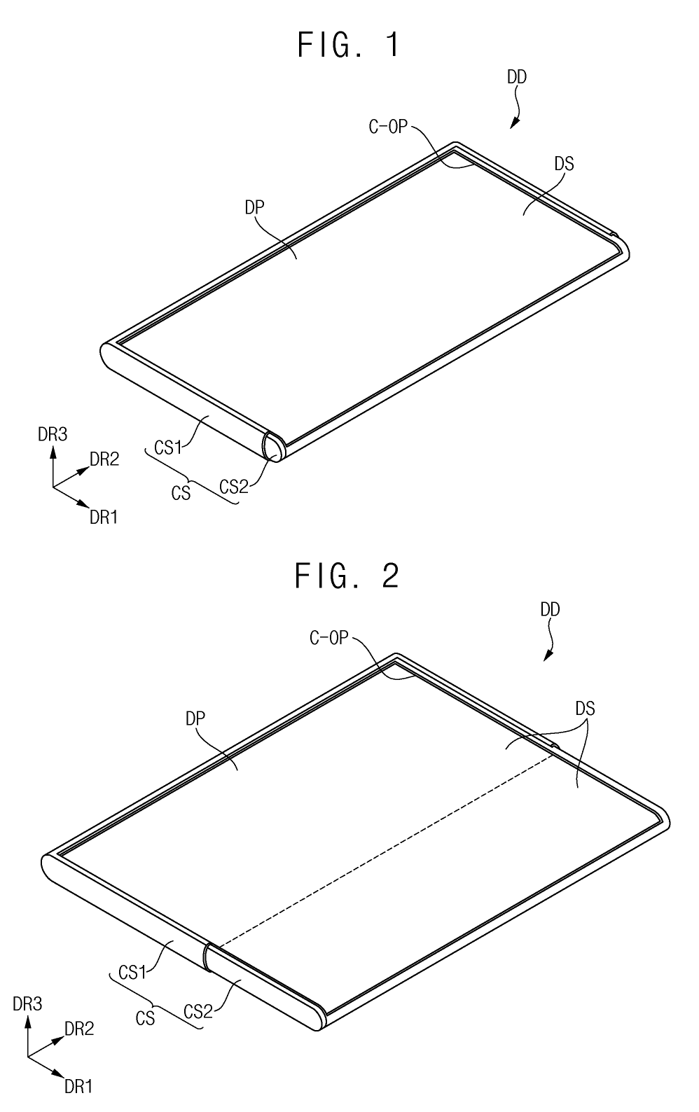

FIGS. 1 and 2 are perspective views illustrating a display device according to an embodiment.

FIG. 1 illustrates a display device DD operated in a first mode, and FIG. 2 illustrates the display device DD operated in a second mode. For example, FIGS. 1 and 2 may be perspective views illustrating a sliding operation of the display device DD.

The display device DD may be a flexible electronic device which is activated according to an electrical signal. In FIGS. 1 and 2, the display device DD is shown as a portable electronic device capable of a sliding operation.

Referring to FIGS. 1 and 2, the display device DD may include a display panel DP and a case CS in which the display panel DP is accommodated. A display surface DS of the display panel DP may be exposed to the outside through a display opening C-OP defined in the case CS.

The case CS may include a first case CS1 and a second case CS2. The first case CS1 and the second case CS2 may be coupled to each other to accommodate the display panel DP. The second case CS2 may be coupled to the first case CS1 to move in a first direction DR1 or in a direction opposite to the first direction DR1. The second case CS2 may be coupled to the first case CS1 to move toward or away from the first case CS1.

The display surface DS of the display panel DP exposed through the display opening C-OP of the case CS may be defined as a plane defined by the first direction DR1 and a second direction DR2 intersecting the first direction DR1. For example, the display panel DP may display an image through the display surface DS in a third direction DR3 intersecting each of the first and second directions DR1 and DR2. For example, the third direction DR3 may be defined as a direction substantially perpendicular to the plane defined by the first and second directions DR1 and DR2. For example, in the present specification, the term “the plan view” of the display panel DP may refer to a state viewed from a thickness direction (i.e., the third direction DR3) of the display panel DP in the second mode.

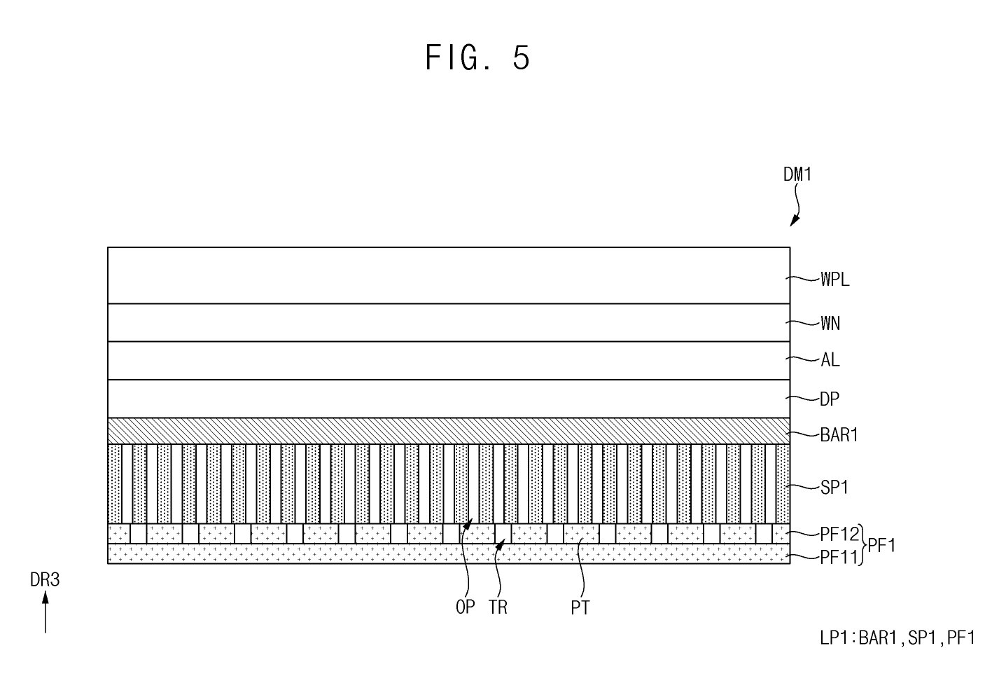

The display panel DP may be a flexible display panel and may be supported by a support plate (e.g., a support plate SP1 in FIG. 5) disposed under the display panel DP. The display panel DP and the support plate may be accommodated in the first case CS1 and the second case CS2, and may be connected to the second case CS2.

An area of the display surface DS of the display panel DP exposed through the display opening C-OP of the case CS may be adjusted according to the movement of the second case CS2. For example, as the second case CS2 moves in the first direction DR1, the display surface DS exposed through the display opening C-OP may increase in the first direction DR1. For example, as the second case CS2 moves in a direction opposite to the first direction DR1, the display surface DS exposed through the display opening C-OP may decrease in the direction opposite to the first direction DR1.

FIG. 1 may illustrate the display device DD in the first mode in which the second case CS2 is disposed closest to the first case CS1 along the first direction DR1 among operation states of the display device DD. In the first mode, a portion of the display panel DP extending from the display panel DP exposed by the display opening C-OP may be wound (or bent) with a predetermined curvature and may be accommodated in the first case CS1. For example, the first mode in which an area of the display surface DS of the display panel DP is set to be minimum may be defined as a basic mode.

FIG. 2 may illustrate the display device DD in the second mode in which the second case CS2 has moved from the first case CS1 along the first direction DR1 among operation states of the display device DD. In the second mode, an area of the display surface DS of the display panel DP exposed through the display opening C-OP may be expanded compared to the first mode. As one end of the display panel DP moves in the first direction DR1 together with the second case CS2, at least a portion of the display panel DP that was accommodated in the first case CS1 in the first mode may be exposed to the outside, and the display surface DS of the display panel DP exposed through the display opening C-OP may be expanded. For example, the second mode in which the area of the display surface DS of the display panel DP in the basic mode is expanded may be defined as an extended mode.

The first mode and the second mode of the display device DD may be determined according to the sliding operation of the case CS and the display panel DP. When a user operates the display device DD from the first mode to the second mode, the user may expand the display surface DS of the display device DD and view an image through the enlarged display surface DS. In addition, when the user operates the display device DD from the second mode to the first mode, the user may reduce the display surface DS of the display device DD and view an image through the reduced display surface DS. That is, by operating the display device DD in one of the first mode and the second mode, the user may variously adjust an area of the display surface DS of the display device DD exposed from the case CS.

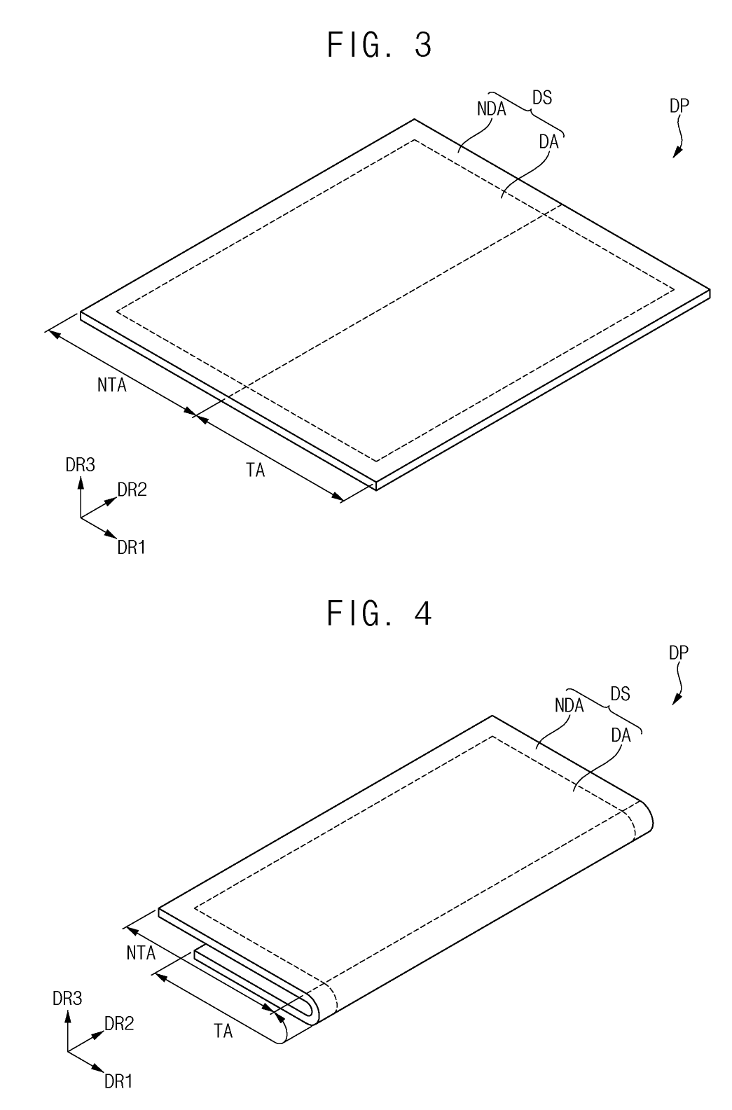

FIGS. 3 and 4 are perspective views illustrating a display panel included in the display device of FIGS. 1 and 2.

FIG. 3 may be a perspective view illustrating the display panel DP accommodated in the case CS illustrated in FIGS. 1 and 2, and FIG. 4 may be a perspective view illustrating a wound state of the display panel DP illustrated in FIG. 3. FIG. 4 may be a view illustrating the display panel DP in the first mode described above.

In FIG. 3, the display panel DP is illustrated in a rectangular shape including long sides extending in the first direction DR1 and short sides extending in the second direction DR2. However, this is merely illustrative, and in the present disclosure, the shape of the display panel DP is not necessarily limited thereto.

Referring to FIGS. 1, 2, 3, and 4, the display surface DS of the display panel DP may include a display area DA and a non-display area NDA.

The display area DA may be an area capable of displaying an image. A plurality of pixels may be disposed in the display area DA. For example, the pixels may be repeatedly disposed along the first direction DR1 and the second direction DR2. By emitting light from each of the pixels, the display area DA may display an image.

The non-display area NDA may be an area where an image is not displayed. The non-display area NDA may be disposed around the display area DA. For example, in the plan view, the non-display area NDA may surround the display area DA. A driver which provides signals and/or voltages to the pixels may be disposed in the non-display area NDA. For example, the driver may include a gate driver, an emission driver, a data driver, and a controller.

The display panel DP may include a non-deformation area NTA and a deformation area TA. The non-deformation area NTA and the deformation area TA may be adjacent to each other. The non-deformation area NTA may be an area exposed to the outside in the first mode (e.g. a basic mode), and the deformation area TA may be an area not exposed to the outside in the first mode. The deformation area TA may be an area capable of a sliding (or bending) operation.

In the first mode, the display surface DS corresponding to the non-deformation area NTA may be exposed through the display opening C-OP, and the display surface DS corresponding to the deformation area TA may not be exposed through the display opening C-OP. The deformation area TA may be accommodated in the first case CS1 in a wound state in the first mode.

In the second mode, the display surface DS corresponding to the non-deformation area NTA and at least a portion of the deformation area TA may be exposed through the display opening C-OP. In the second mode, the second case CS2 may move along the first direction DR1, and at least a portion of the deformation area TA may extend from the non-deformation area NTA in the first direction DR1.

In FIGS. 1, 2, 3, and 4,, the display device DD is illustrated as a flexible electronic device capable of a sliding operation, and the display panel DP is illustrated as a flexible display panel capable of a sliding operation. However, the embodiments of the present disclosure are not necessarily limited thereto. For example, the display device DD including the display panel DP may be flexible so that at least a portion thereof is foldable, bendable, rollable, stretchable, or slidable. For example, the display device DD including the display panel DP may include a curved surface portion having a constant curvature or a varying curvature at least in portion of an edge of the display panel DP.

FIG. 5 is a cross-sectional view illustrating a display module according to an embodiment.

Referring to FIG. 5, a display module DM1 may include the display panel DP, a window WN, an adhesive layer AL, a window protection layer WPL, and a metal plate LP1.

The display panel DP may include the pixels which emit light. In an embodiment, the display panel DP may be a flexible display panel. For example, the display panel DP may include electronic elements disposed on a flexible substrate.

The window WN may be disposed on the display panel DP. The window WN may protect the display panel DP from external impact. The window WN may include a material having high transmittance and may transmit light generated from the display panel DP.

The window WN may include an optically transparent material. The window WN may include glass. For example, the window WN may include tempered glass (e.g., ultra-thin glass (UTG)). However, the embodiments of the present disclosure are not necessarily limited thereto, and the window WN may include a synthetic resin film, sapphire, and the like. The window WN may have a multi-layer structure or a single-layer structure. For example, the window WN may include a plurality of synthetic resin films bonded by an adhesive, or may include a glass substrate and a synthetic resin film bonded by an adhesive.

The adhesive layer AL may be disposed between the display panel DP and the window WN. The adhesive layer AL may adhere the window WN onto the display panel DP. The adhesive layer AL may include a pressure sensitive adhesive (PSA), an optically clear adhesive (OCA), an optically clear resin (OCR), or the like, but a type of adhesive is not necessarily limited thereto.

The window protection layer WPL may be disposed on the window WN. The window protection layer WPL may protect the window WN from external impact. The window protection layer WPL may prevent or minimize scratches from occurring on an upper surface of the window WN. The window protection layer WPL may perform at least one function among shatter prevention, impact absorption, dent prevention, fingerprint prevention, and anti-glare of the window WN.

The window protection layer WPL may include a polymer resin. For example, the window protection layer WP may include polyimide, polycarbonate, polyamide, triacetyl cellulose, polymethyl methacrylate, polyethylene terephthalate, and the like. Although not illustrated in the drawings, various functional layers such as a hard coating layer, a fingerprint prevention layer, and an anti-reflection layer may be additionally disposed on the window protection layer WPL.

The metal plate LP1 may be disposed under the display panel DP. The metal plate LP1 may include a barrier layer BAR1, a support plate SP1, and a protective film PF1.

The barrier layer BAR1 may be disposed under the display panel DP. The barrier layer BAR1 may improve impact resistance of the display panel DP to prevent or minimize deformation of the display panel DP. For example, the barrier layer BAR1 may include a polymer resin. For example, the barrier layer BAR1 may include polyimide, polyethylene terephthalate, and the like, but the present disclosure is not necessarily limited thereto. For example, the barrier layer BAR1 may have a color having high light absorptance. The barrier layer BAR1 may block light introduced to a lower side of the display panel DP and may prevent or minimize occurrence of a rear-side see-through phenomenon of the display panel DP.

The support plate SP1 may be disposed under the barrier layer BAR1. The support plate SP1 may support the display panel DP. For example, rigidity of the support plate SP1 may be greater than rigidity of the display panel DP. The support plate SP1 may prevent or minimize deformation of the display panel DP due to an external force of a user and the like.

In an embodiment, the support plate SP1 may include a metal or an alloy. For example, the support plate SP1 may include stainless steel (SUS), titanium, aluminum, magnesium, a titanium alloy, an aluminum alloy, a magnesium alloy, and the like.

In an embodiment, the support plate SP1 may include glass or plastic. For example, the support plate SP1 may include carbon fiber reinforced plastic (CFRP), glass fiber reinforced plastic (GFRP), and the like. However, the present disclosure is not necessarily limited thereto, and the support plate SP1 may include various materials capable of stably supporting the display panel DP.

Openings OP penetrating the support plate SP1 in a thickness direction (e.g., the third direction DR3) may be defined in the support plate SP1. The support plate SP1 may facilitate a sliding operation of the display panel DP. As the openings OP are defined in the support plate SP1, the support plate SP1 may have flexibility in response to the sliding operation of the display panel DP.

An area in which the openings OP are defined in the support plate SP1 may overlap a whole surface of the display panel DP (e.g., a whole surface of the display surface DS in FIG. 3) in the plan view. The openings OP may overlap a transformable area of the display panel DP (e.g., the deformation area TA in FIG. 3) and a non-deformation area (e.g., the non-deformation area NTA in FIG. 3) in the plan view. As the openings OP are formed (or defined) over a whole surface (e.g., an entirety) of the support plate SP1, the display module DM1 (or the display device DD of FIG. 1) may be light-weighted.

The protective film PF1 may be disposed under the support plate SP1.

In the protective film PF1, trenches TR recessed from a first surface of the protective film PF1 (e.g., one surface adjacent to the support plate SP1) toward a second surface of the protective film PF1 opposite to the first surface (e.g., one surface spaced from the support plate SP1) may be defined. The trenches TR may be formed (or defined) over a whole surface of the protective film PF1. That is, the trenches TR may overlap the deformation area of the display panel DP (e.g., the deformation area TA in FIG. 3) and the non-deformation area (e.g., the non-deformation area NTA in FIG. 3) in the plan view.

The trenches TR of the protective film PF1 may at least partially overlap the openings OP of the support plate SP1 in the plan view. In an embodiment, each of the trenches TR may overlap at least one of the openings OP in the plan view. In an embodiment, each of the trenches TR may be spatially connected (i.e., communicate with) to and overlap the opening OP in the plan view among the openings OP.

The protective film PF1 may have a multi-layer structure. In an embodiment, the protective film PF1 may include a first protective film PF11 and a second protective film PF12 disposed on the first protective film PF11. The second protective film PF12 may be disposed between the first protective film PF11 and the support plate SP1.

The second protective film PF12 may include a plurality of patterns PT. The plurality of patterns PT may be spaced apart from each other and may define the trenches TR. The patterns PT may protrude in a thickness direction (e.g., the third direction DR3) from an upper surface of the first protective film PF11 to define the trenches TR recessed from the upper surface of the second protective film PF12 toward the upper surface of the first protective film PF11.

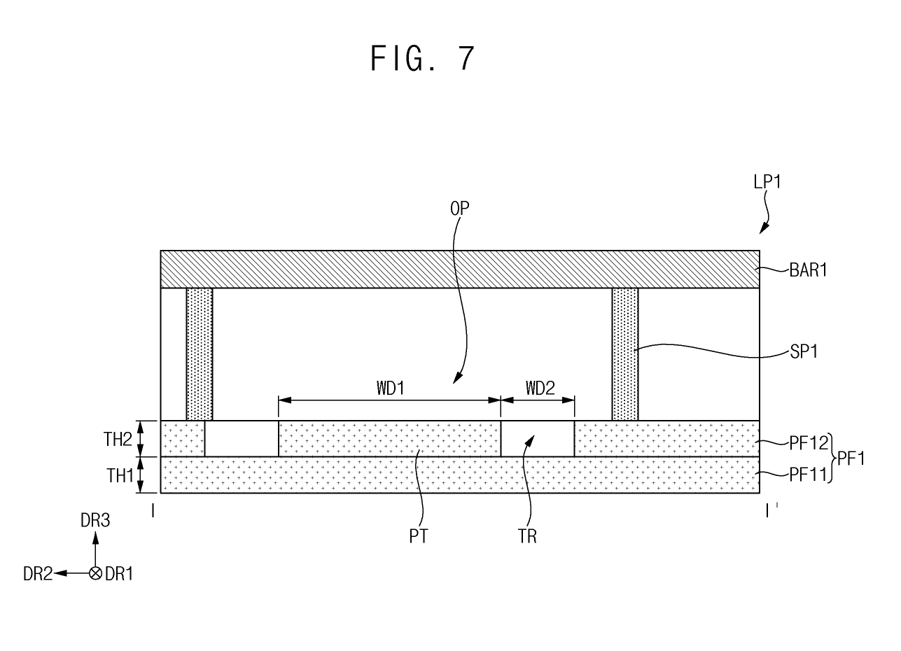

In an embodiment, the first protective film PF11 may include a first base layer and a first adhesive layer (not illustrated in FIG. 7) disposed on the first base layer, and the second protective film PF12 may include a second base layer and a second adhesive layer (not illustrated in FIG. 7) disposed on the second base layer. The first adhesive layer may adhere the first protective film PF11 (e.g., the first base layer) and the second protective film PF12 (e.g., the second base layer), and the second adhesive layer may adhere the second protective film PF12 (e.g., the second base layer) and the support plate SP1.

The first and second protective films PF11 and PF12 may include the same material. In an embodiment, the first and second protective films PF11 and PF12 may include a polymer resin. For example, the first and second protective films PF11 and PF12 (e.g., the first and second base layers) may include polyethylene terephthalate, but the present disclosure is not necessarily limited thereto. For example, the second protective film PF12 may be defined as a film in which the trench TR is formed (or patterned) on the first protective film PF11.

The display module DM1 may be assembled into various sets and may be provided as various types of electronic devices (e.g., the display device DD of FIG. 1). The electronic device may be manufactured using the display module DM1. The protective film PF1 may be a component disposed under the support plate SP1 to protect the display panel DP and the support plate SP1 during a manufacturing process of the electronic device. For example, a state in which the metal plate LP1 (e.g., the barrier layer BAR1, the support plate SP1, and the protective film PF1) is attached to a lower portion of the display panel DP may be defined as the display module DM1.

The protective film PF1 may maintain a state of being attached to a lower portion of the support plate SP1 until the display module DM1 is assembled into a set. Accordingly, the protective film PF1 may protect the display panel DP and the support plate SP1 until set assembly. At set assembly, the protective film PF1 may be removed from the display module DM1, and a final product of the electronic device (e.g., the display device DD of FIG. 1) may not include the protective film PF1. For example, the protective film PF1 may be referred to as a release film.

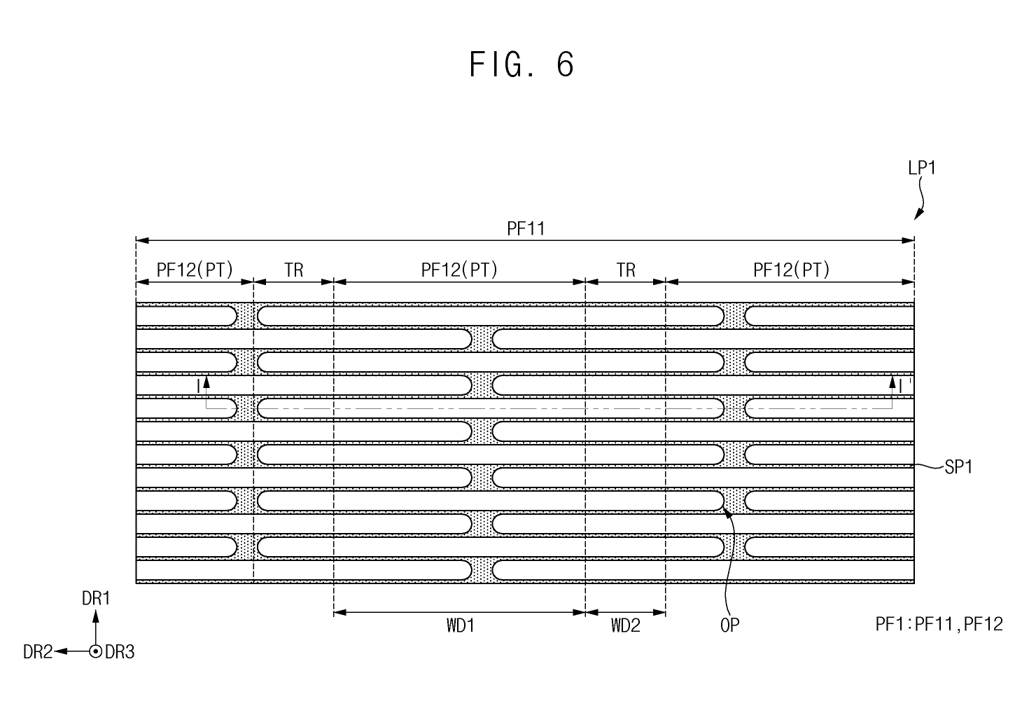

FIG. 6 is a plan view illustrating a portion of a metal plate included in the display module of FIG. 5. FIG. 7 is a cross-sectional view taken along line I-I’ of FIG. 6.

In FIG. 7, a plan overlapping structure of the metal plate LP1 is illustrated, and hatching is indicated only for the support plate SP1.

Referring to FIGS. 5, 6, and 7, the support plate SP1 and the barrier layer BAR1 may be sequentially disposed on the protective film PF1, the openings OP may be defined in the support plate SP1, and the trenches TR may be defined in the protective film PF1.

In an embodiment, the opening OP and the trench TR which overlap each other in the plan view may have shapes intersecting each other. Each of the openings OP may extend in the second direction DR2. The openings OP may be spaced apart from each other and may be arranged in a zigzag along the first direction DR1. Each of the trenches TR may extend in the first direction DR1. The trenches TR may be spaced apart from each other and may be arranged along the second direction DR2. Each of the patterns PT of the second protective film PF12 may extend in the first direction DR1. The patterns PT may be spaced apart from each other and may be arranged along the second direction DR2. The patterns PT and the trenches TR may be alternately arranged along the second direction DR2.

In the plan view, the first protective film PF11 may entirely overlap the support plate SP1, and the second protective film PF12 may partially overlap the support plate SP1. The first protective film PF11 may entirely cover a lower surface of the support plate SP1, and the second protective film PF12 may partially cover the lower surface of the support plate SP1.

The pattern PT may have a first width WD1 in a width direction (e.g., the second direction DR2), and the trench TR may have a second width WD2 in the width direction (e.g., the second direction DR2). The length of the trench TR in the first direction DR1 may be longer than the second width WD2 in the width direction. In an embodiment, the first width WD1 may be greater than or equal to the second width WD2. For example, the first width WD1 may be about 4 millimeters (mm), and the second width WD2 may be about 4 mm or less. For example, preferably, the first width WD1 may be about 4 mm, and the second width WD2 may be about 2 mm.

However, the embodiments of the present disclosure are not necessarily limited thereto, and the first width WD1 and the second width WD2 may be variously changed within a range in which a contact area between the second protective film PF12 and the support plate SP1 is sufficient to maintain an adhesive force between the protective film PF1 and the support plate SP1, and in which an error does not occur in subsequent processes.

The first protective film PF11 may have a first thickness TH1 in a thickness direction (e.g., the third direction DR3), and the second protective film PF12 may have a second thickness TH2 in the thickness direction (e.g., the third direction DR3). In an embodiment, the first thickness TH1 and the second thickness TH2 may be substantially the same as each other. For example, the first and second thicknesses TH1 and TH2 may be about 75 micrometers (μm) or more, but the present disclosure is not necessarily limited thereto. For example, each of the first and second thicknesses TH1 and TH2 may be about 100 μm, but the present disclosure is not necessarily limited thereto.

In an embodiment, each of the trenches TR may overlap at least one of the openings OP in the plan view and may be spatially connected (i.e., communicate with) to at least one of the openings OP. Accordingly, during a lamination process of the display panel DP and the metal plate LP1, the openings OP may not be sealed by the protective film PF1.

The display panel DP and the metal plate LP1 may be laminated together through a lamination process. The lamination between the display panel DP and the metal plate LP1 may be performed through vacuum lamination. During the lamination process, the display panel DP and the metal plate LP1 are brought into close contact in a vacuum state, and at this time, air existing in the openings OP may escape to the outside through the trenches TR defined in the protective film PF1. That is, during the lamination process, air existing in the openings OP in an atmospheric state may be easily discharged to the outside through the openings OP and the trenches TR according to a changed pressure difference.

The trenches TR may be defined as air passages connecting the openings OP to the outside. Since each of the trenches TR is connected to at least one of the openings OP, a passage communicating from the openings OP to the outside through the trenches TR may be formed, and a flow (or inflow and outflow) of air may occur therethrough. Accordingly, even when external air pressure is changed, internal air pressure of the openings OP may change correspondingly, so that occurrence of defects such as bubbles generated between the display panel DP and the metal plate LP1 during the lamination process and deformation of the display panel DP may be prevented or minimized. Although the protective film PF1 is removed during a process of manufacturing an electronic device (e.g., the display device DD of FIG. 1) using the display module DM1 and is not included in the electronic device, the protective film PFb may affect the possibility of occurrence of defects such as bubble generation inside the electronic device which may occur during a manufacturing process of the electronic device and deformation of the display panel DP included in the electronic device.

In contrast, when no separate trench (e.g., an air passage) exists in the protective film PF1, the openings OP of the support plate SP1 are sealed by the barrier layer BAR1 and the protective film PF1 so that air remains inside the openings OP. During the lamination process of the display panel DP and the metal plate LP1, as the outside is changed to a vacuum state, the air existing inside the openings OP may expand, and lifting may occur between the support plate SP1 and the protective film PF1. In this case, bubbles between the display panel DP and the metal plate LP1 and deformation of the display module DM1 may occur. Alternatively, when the outside is subsequently changed to an atmospheric state, due to a pressure difference between the air inside the openings OP and external atmosphere, an upper component of the support plate SP1 (e.g., the display panel DP) may be sucked toward the openings OP. In this case, deformation such as wrinkles occurring in the upper component may be visible from the outside, thereby resulting in poor visibility.

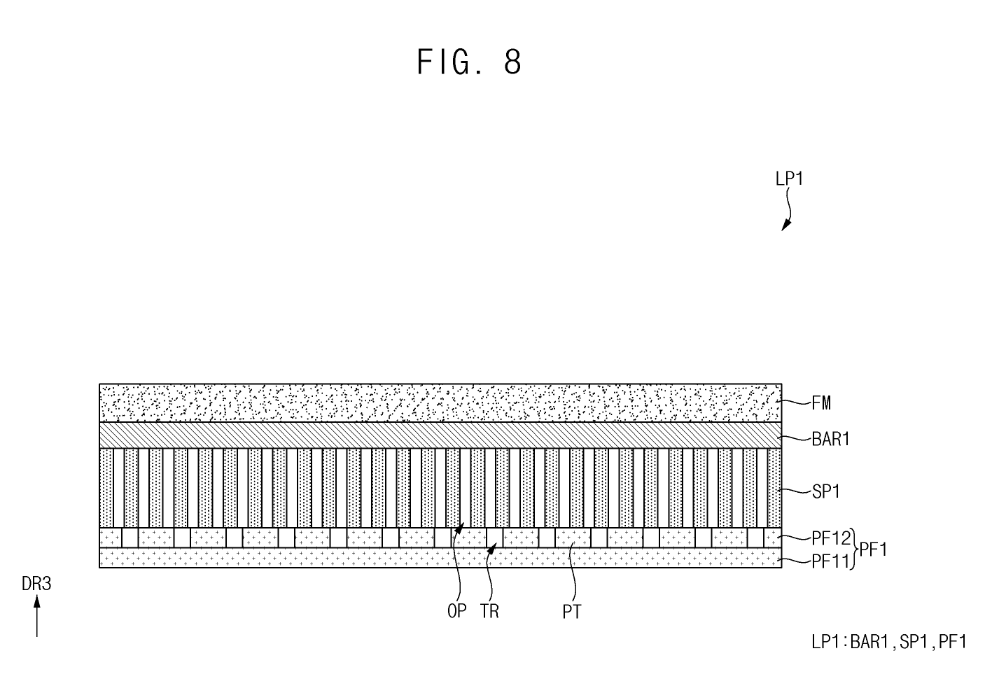

FIG. 8 is a cross-sectional view illustrating a state in which a metal plate included in the display module of FIG. 5 is provided. FIG. 8 may be a cross-sectional view illustrating a state in which the metal plate LP1 is provided from an external supplier.

Referring to FIGS. 5 and 8, when the metal plate LP1 is provided from the external supplier, a film FM for protecting one surface (e.g., an upper surface) of the metal plate LP1 may be attached to the metal plate LP1. The metal plate LP1 may be provided in a state in which the film FM is attached to an upper surface of the barrier layer BAR1, and the protective film PF1 is attached to a lower surface of the support plate SP1.

The film FM may be disposed on the barrier layer BAR1 to protect the metal plate LP1, and the protective film PF1 may be disposed under the support plate SP1 to protect the support plate SP1.

The film FM may maintain a state of being attached to the upper surface of the metal plate LP1 until the metal plate LP1 is laminated with the display panel DP. Accordingly, the film FM may protect the metal plate LP1 until the lamination process between the metal plate LP1 and the display panel DP. During the lamination process, the film FM may be removed from the metal plate LP1, and the display module DM1 may be provided.

In the metal plate LP1 of the display module DM1 according to an embodiment of the present disclosure, the metal plate LP1 may include the support plate SP1 and the protective film PF1 disposed under the display panel DP. The openings OP may be defined in the support plate SP1, and the trenches TR may be defined in the protective film PF1. As the openings OP are connected to the outside through the trenches TR, air may flow smoothly into the openings OP. Since the air pressure inside the openings OP may correspondingly change even when external air pressure changes, occurrence of defects such as bubbles inside the display module DM1 and deformation of the display panel DP may be prevented or minimized. Accordingly, reliability of the display module DM1 and an electronic device (e.g., the display device DD of FIG. 1) manufactured by using the same may be improved.

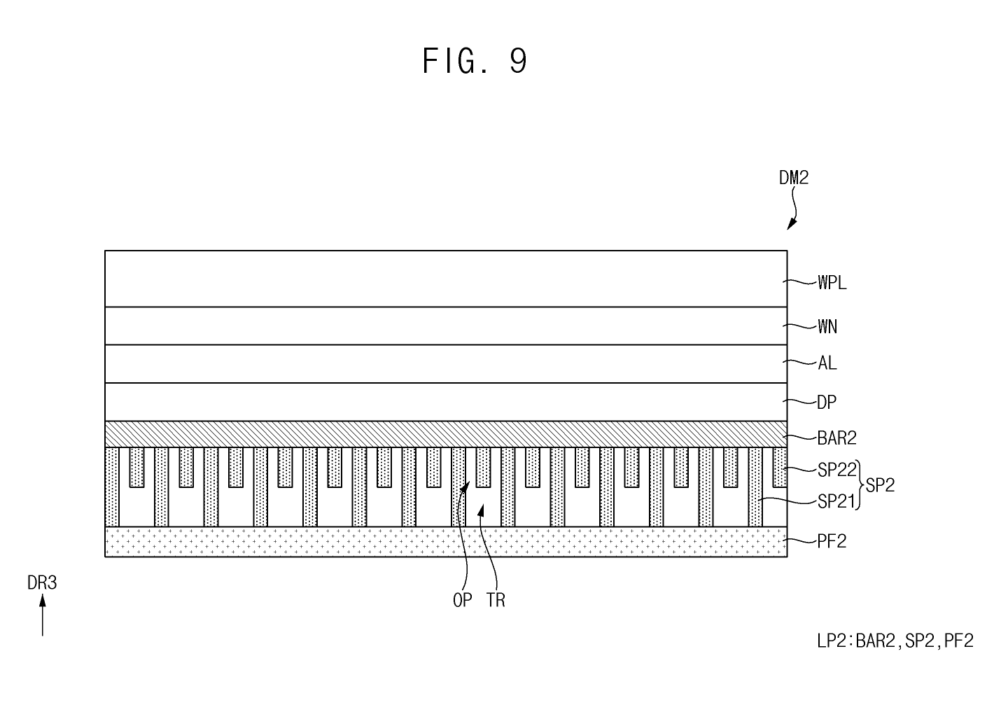

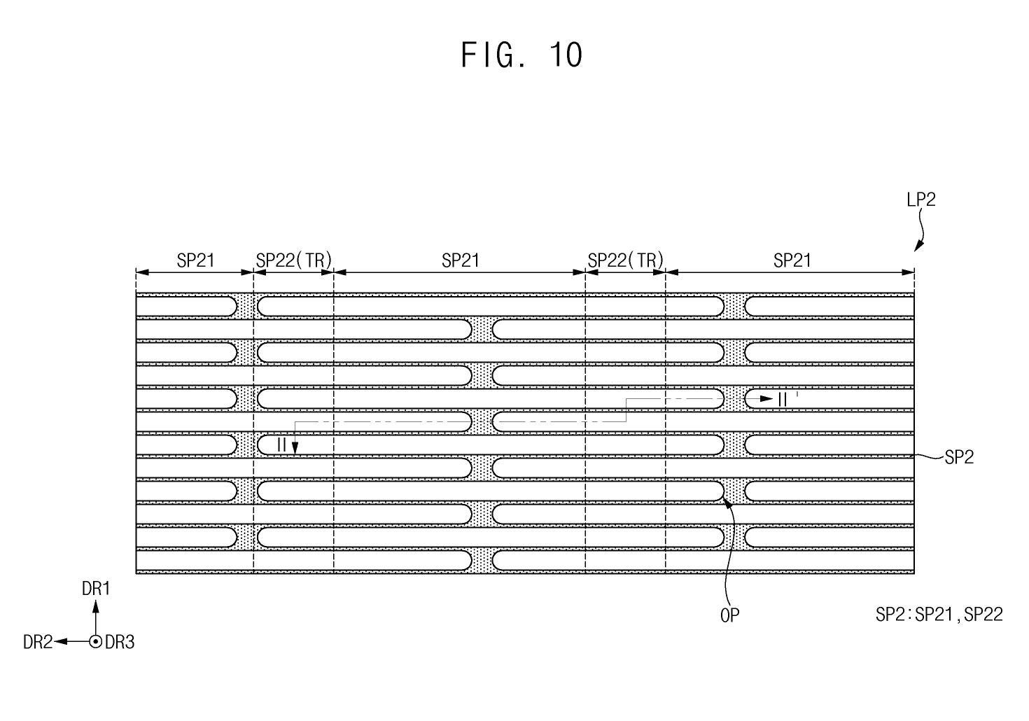

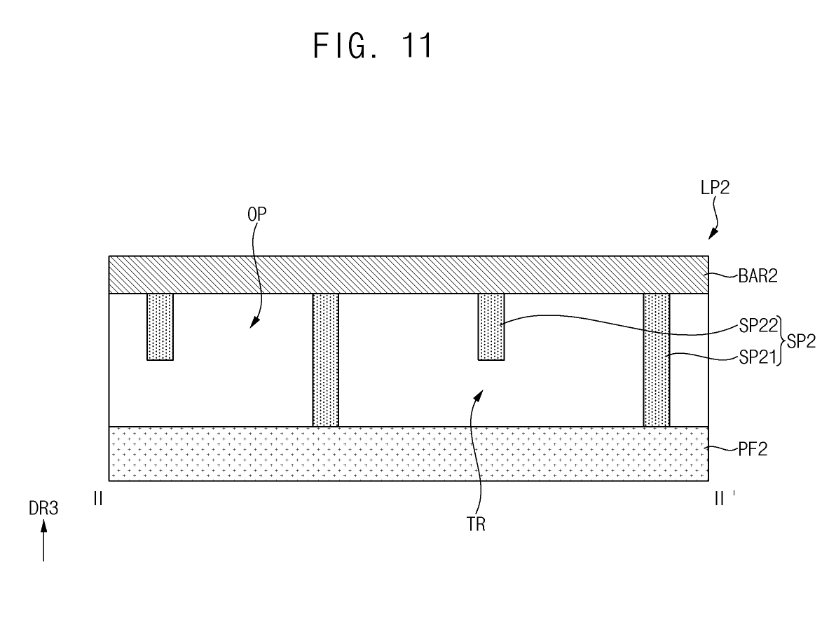

FIG. 9 is a cross-sectional view illustrating a display module according to another embodiment. FIG. 10 is a plan view illustrating a portion of a metal plate included in the display module of FIG. 9. FIG. 11 is a cross-sectional view taken along line II-II’ of FIG. 10.

In FIG. 10, a plan overlapping structure of the metal plate LP2 is illustrated, and hatching is indicated only for the support plate SP2.

A display module DM2 described with reference to FIGS. 9, 10, and 11 , may be substantially the same as or similar to the display module DM1 described with reference to FIGS. 5, 6, 7, and 8, except for the metal plate LP2. Hereinafter, redundant descriptions are omitted or simplified.

Referring to FIGS. 9, 10, and 11, the display module DM2 may include a display panel DP, a window WN, an adhesive layer AL, a window protection layer WPL, and a metal plate LP2.

The display panel DP may include pixels which emit light and may be a flexible display panel. The window WN and the window protection layer WPL may be sequentially disposed on the display panel DP, and the adhesive layer AL may adhere the window WN onto the display panel DP.

The metal plate LP2 may be disposed under the display panel DP. The metal plate LP2 may include a barrier layer BAR2, a support plate SP2, and a protective film PF2.

The barrier layer BAR2 may be disposed under the display panel DP. The barrier layer BAR2 may improve impact resistance of the display panel DP to prevent or minimize deformation of the display panel DP.

The support plate SP2 may be disposed under the barrier layer BAR2. The support plate SP2 may support the display panel DP and may prevent or minimize deformation of the display panel DP.

Openings OP penetrating the support plate SP2 in a thickness direction (e.g., the third direction DR3) may be defined in the support plate SP2. Accordingly, the support plate SP2 may have flexibility corresponding to a sliding operation of the display panel DP and may facilitate the sliding operation of the display panel DP.

In the support plate SP2, trenches TR recessed from a first surface of the support plate SP2 (e.g., one surface spaced from the display panel DP) toward a second surface of the support plate SP2 opposite to the first surface (e.g., one surface adjacent to the display panel DP) may be defined. Each of the trenches TR may be spatially connected (i.e., communicate with) to at least one of the openings OP.

The openings OP and the trenches TR may be defined over a whole surface of the support plate SP2. An area in which the openings OP and the trenches TR are defined in the support plate SP2 may overlap a whole surface of the display panel DP (e.g., a whole surface of the display surface DS in FIG. 3) in the plan view. That is, the openings OP and the trenches TR may overlap a deformation area (e.g., the deformation area TA in FIG. 3) and a non-deformation area (e.g., the non-deformation area NTA in FIG. 3) of the display panel DP in the plan view.

The support plate SP2 may include first patterns SP21 and second patterns SP22. The first patterns SP21 and the second patterns SP22 may be connected to each other.

The first patterns SP21 may be defined as portions where a first surface (e.g., a lower surface) of the support plate SP2 contacts a lower component (e.g., the protective film PF2) and a second surface (e.g., an upper surface) of the support plate SP2 contacts an upper component (e.g., the barrier layer BAR2).

The second patterns SP22 may be defined as portions where the first surface (e.g., the lower surface) of the support plate SP2 is recessed toward the second surface (e.g., the upper surface) to define the trenches TR. The second patterns SP22 may be defined as portions where the first surface of the support plate SP2 does not contact (or is spaced from) the lower component (e.g., the protective film PF2), and the second surface of the support plate SP2 contacts the upper component (e.g., the barrier layer BAR2).

A thickness (e.g., a length in the third direction DR3) of the first patterns SP21 may be greater than a thickness (e.g., a length in the third direction DR3) of the second patterns SP22. The first patterns SP21 may be arranged in the first direction DR1, and the second patterns SP22 may be arranged in the first direction DR1. The first patterns SP21 and the second patterns SP22 may be alternately arranged along the second direction DR2. For example, the second patterns SP22 may be formed by etching a portion of the support plate SP2.

In an embodiment, each of the trenches TR may be spatially connected (i.e., communicate with) to at least one of the openings OP. Accordingly, during a lamination process of the display panel DP and the metal plate LP2, the openings OP in the support plate SP2 may not be sealed.

The protective film PF2 may be disposed under the support plate SP2 and may cover a lower surface of the support plate SP2. The protective film PF2 may be disposed under the support plate SP2 until the display module DM2 is assembled into a set to protect the display panel DP and the support plate SP2.

For example, the protective film PF2 may include a base layer and an adhesive layer disposed on the base layer, and the adhesive layer may adhere the protective film PF2 (e.g., the base layer) and the support plate SP2. For example, the protective film PF2 (e.g., the base layer) may include polyethylene terephthalate, but the present disclosure is not necessarily limited thereto.

The display panel DP and the metal plate LP2 may be laminated together through a lamination process. During the lamination process, the display panel DP and the metal plate LP2 may be brought into close contact in a vacuum state, and air existing in the openings OP may be easily discharged to the outside through the trenches TR.

The trenches TR may be defined as air passages connecting the openings OP to the outside. Since each of the trenches TR is connected to at least one of the openings OP, a passage communicating from the openings OP to the outside through the trenches TR may be formed, and a flow (or inflow and outflow) of air may occur therethrough. Accordingly, even when external air pressure changes, internal air pressure of the openings OP may change correspondingly, so that occurrence of defects such as bubbles generated between the display panel DP and the metal plate LP2 during the lamination process and deformation of the display panel DP may be prevented or minimized.

When the metal plate LP2 is provided from an external supplier, the metal plate LP2 may be provided in a state in which a film (e.g., the film FM in FIG. 8) is attached to an upper surface of the barrier layer BAR2, and the protective film PF2 is attached to a lower surface of the support plate SP2. During the lamination process, the film may be removed from the metal plate LP2, and the display module DM2 may be provided.

The display module DM2 may be assembled into various sets and may be manufactured as various types of electronic devices (e.g., the display device DD in FIG. 1). During set assembly, the protective film PF2 may be removed from the display module DM2, and the electronic device (e.g., the display device DD in FIG. 1) may be provided.

In the metal plate LP2 of the display module DM2 according to an embodiment of the present disclosure, the metal plate LP2 may include the support plate SP2 disposed under the display panel DP. The openings OP and the trenches TR may be defined in the support plate SP2. As the openings OP are connected to the outside through the trenches TR, air may flow smoothly into the openings OP. Since the air pressure inside the openings OP may correspondingly change even when external air pressure changes, occurrence of defects such as bubbles inside the display module DM2 and deformation of the display panel DP may be prevented or minimized. Accordingly, reliability of the display module DM2 and an electronic device (e.g., the display device DD of FIG. 1) manufactured by using the same may be improved.

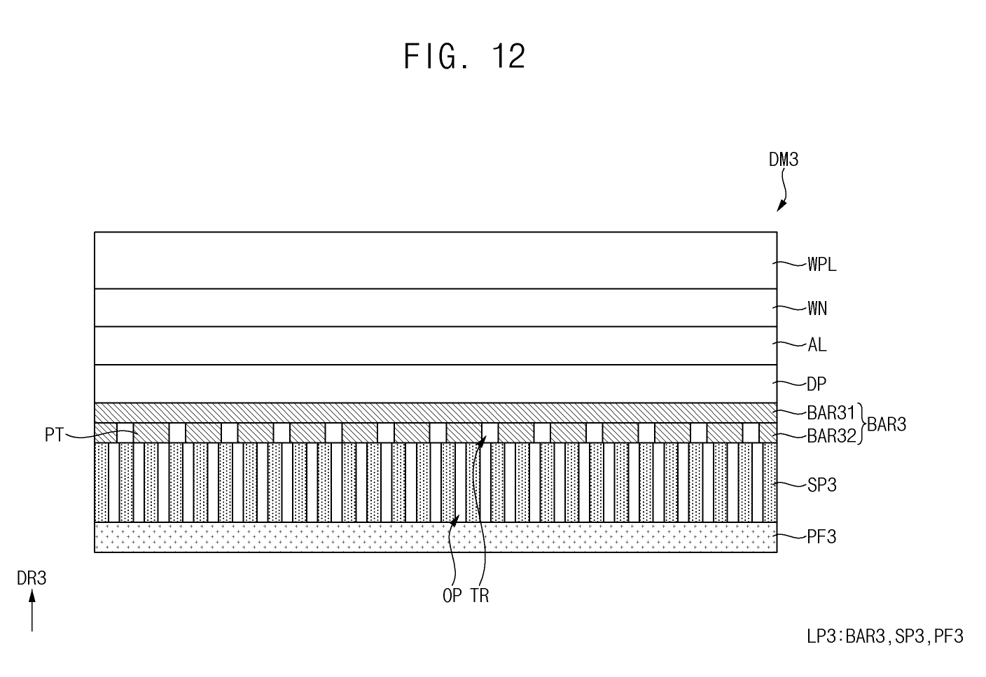

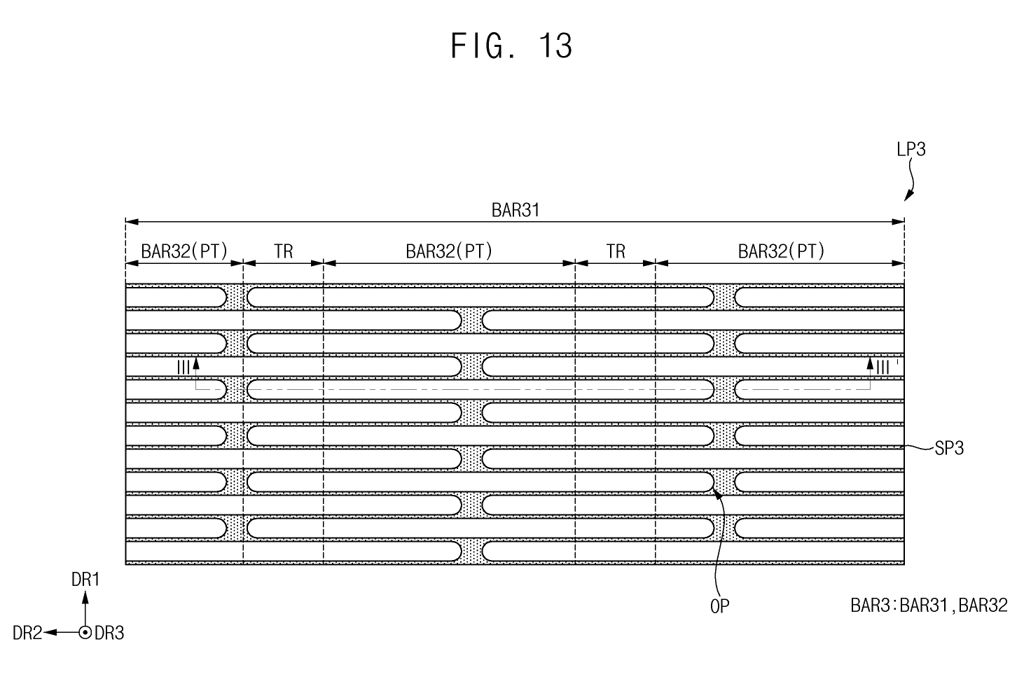

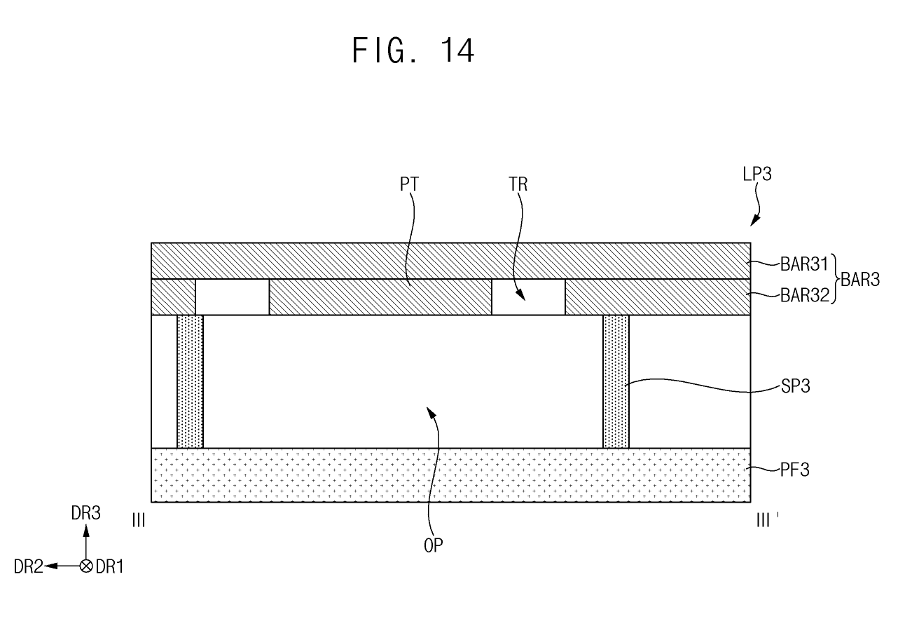

FIG. 12 is a cross-sectional view illustrating a display module according to still another embodiment. FIG. 13 is a plan view illustrating a portion of a metal plate included in the display module of FIG. 12. FIG. 14 is a cross-sectional view taken along line III-III’ of FIG. 13.

In FIG. 13, a plan overlapping structure of the metal plate LP3 is illustrated, and hatching is indicated only for the support plate SP3.

A display module DM3 described with reference to FIGS. 12, 13, and 14, may be substantially the same as or similar to the display module DM1 described with reference to FIGS. 5, 6, 7,and 8, except for the metal plate LP3. Hereinafter, redundant descriptions are omitted or simplified.

Referring to FIGS. 12, 13, and 14, the display module DM3 may include a display panel DP, a window WN, an adhesive layer AL, a window protection layer WPL, and a metal plate LP3.

The display panel DP may include pixels which emit light and may be a flexible display panel. The window WN and the window protection layer WPL may be sequentially disposed on the display panel DP, and the adhesive layer AL may adhere the window WN onto the display panel DP.

The metal plate LP3 may be disposed under the display panel DP. The metal plate LP3 may include a barrier layer BAR3, a support plate SP3, and a protective film PF3.

The support plate SP3 may be disposed under the display panel DP. The support plate SP3 may support the display panel DP and may prevent or minimize deformation of the display panel DP.

Openings OP penetrating the support plate SP3 in a thickness direction (e.g., the third direction DR3) may be defined in the support plate SP3. Accordingly, the support plate SP3 may have flexibility corresponding to a sliding operation of the display panel DP and may facilitate the sliding operation of the display panel DP. The openings OP may be defined over a whole surface of the support plate SP3. That is, the openings OP may overlap a transformable area (e.g., the deformation area TA in FIG. 3) and a non-deformation e area (e.g., the non-deformation area NTA in FIG. 3) of the display panel DP in the plan view.

The barrier layer BAR3 may be disposed between the display panel DP and the support plate SP3. The barrier layer BAR3 may improve impact resistance of the display panel DP to prevent or minimize deformation of the display panel DP.

In the barrier layer BAR3, trenches TR recessed from a first surface of the barrier layer BAR3 (e.g., one surface adjacent to the support plate SP3) toward a second surface of the barrier layer BAR3 opposite to the first surface (e.g., one surface spaced from the support plate SP3) may be defined. The trenches TR may be defined over a whole surface of the barrier layer BAR3. That is, the trenches TR may overlap the deformation area of the display panel DP (e.g., the deformation area TA in FIG. 3) and the non-deformation area (e.g., the non-deformation area NTA in FIG. 3) in the plan view.

In FIGS. 12-14, the barrier layer BAR3 may be referred to as a protective film.

In an embodiment, each of the trenches TR of the barrier layer BAR3 may overlap at least one of the openings OP of the support plate SP3 in the plan view. In an embodiment, each of the trenches TR may be spatially connected (i.e., communicate with) to and overlap the opening OP in the plan view among the openings OP.

The barrier layer BAR3 may have a multi-layer structure. In an embodiment, the barrier layer BAR3 may include a first barrier layer BAR31 and a second barrier layer BAR32 disposed below the first barrier layer BAR31. The second barrier layer BAR32 may be disposed between the first barrier layer BAR31 and the support plate SP3.

The second barrier layer BAR32 may include a plurality of patterns PT. The plurality of patterns PT may be spaced apart from each other and may define the trenches TR. The patterns PT may protrude in a thickness direction (e.g., a direction opposite to the third direction DR3) from a lower surface of the first barrier layer BAR31 to define the trenches TR recessed from the lower surface of the second barrier layer BAR32 toward the lower surface of the first barrier layer BAR31.

In an embodiment, the first barrier layer BAR31 may include a first adhesive layer and a first base layer disposed on the first adhesive layer, and the second barrier layer BAR32 may include a second adhesive layer and a second base layer disposed on the second adhesive layer. The first adhesive layer may adhere the first barrier layer BAR31 (e.g., the first base layer) and the second barrier layer BAR32 (e.g., the second base layer), and the second adhesive layer may adhere the second barrier layer BAR32 (e.g., the second base layer) and the support plate SP3.

The first and second barrier layers BAR31 and BAR32 may include the same material. In an embodiment, the first and second barrier layers BAR31 and BAR32 may include a polymer resin. For example, the first and second barrier layers BAR31 and BAR32 (e.g., the first and second base layers) may include polyethylene terephthalate, but the present disclosure is not necessarily limited thereto. For example, the second barrier layer BAR32 may be defined as a film in which the trench TR is formed (or patterned) on the first barrier layer BAR31. For example, a thickness (e.g., a length in the third direction DR3) of the first barrier layer BAR31 and a thickness (e.g., a length in the third direction DR3) of the second barrier layer BAR32 may be substantially the same as each other.

In an embodiment, the opening OP and the trench TR which overlap each other in the plan view may have shapes intersecting each other. Each of the trenches TR may extend in the first direction DR1. The trenches TR may be spaced apart from each other and may be arranged along the second direction DR2. Each of the patterns PT of the second barrier layer BAR32 may extend in the first direction DR1. The patterns PT may be spaced apart from each other and may be arranged along the second direction DR2. The patterns PT and the trenches TR may be alternately arranged along the second direction DR2.

The first barrier layer BAR31 may entirely overlap the support plate SP3 in the plan view and may entirely cover an upper surface of the support plate SP3, and the second barrier layer BAR32 may partially overlap the support plate SP3 in the plan view and may partially cover the upper surface of the support plate SP3.

In an embodiment, each of the trenches TR may overlap at least one of the openings OP in the plan view and may be spatially connected (i.e., communicate with) to at least one of the openings OP. Accordingly, during a lamination process of the display panel DP and the metal plate LP3, the openings OP may not be sealed by the barrier layer BAR3.

The protective film PF3 may be disposed under the support plate SP3 and may cover a lower surface of the support plate SP3. The protective film PF3 may be disposed under the support plate SP3 until the display module DM3 is assembled into a set to protect the display panel DP and the support plate SP3.

The display panel DP and the metal plate LP3 may be laminated together through a lamination process. During the lamination process, the display panel DP and the metal plate LP3 may be brought into close contact in a vacuum state, and air existing in the openings OP may be easily discharged to the outside through the trenches TR.

The trenches TR may be defined as air passages connecting the openings OP to the outside. Since each of the trenches TR is connected to at least one of the openings OP, a passage communicating from the openings OP to the outside through the trenches TR may be formed, and a flow (or inflow and outflow) of air may occur therethrough. Accordingly, even when external air pressure changes, internal air pressure of the openings OP may change correspondingly, so that occurrence of defects such as bubbles generated between the display panel DP and the metal plate LP3 during the lamination process and deformation of the display panel DP may be prevented or minimized.

When the metal plate LP3 is provided from an external supplier, the metal plate LP3 may be provided in a state in which a film (e.g., the film FM of FIG. 8) is attached to an upper surface of the barrier layer BAR3, and the protective film PF3 is attached to a lower surface of the support plate SP3. During the lamination process, the film may be removed from the metal plate LP3, and the display module DM3 may be provided.

The display module DM3 may be assembled into various sets and may be manufactured as various types of electronic devices (e.g., the display device DD of FIG. 1). During set assembly, the protective film PF3 may be removed from the display module DM3, and the electronic device (e.g., the display device DD of FIG. 1) may be provided.

In the metal plate LP3 of the display module DM3 according to an embodiment of the present disclosure, the metal plate LP3 may include the barrier layer BAR3 and the support plate SP3 disposed under the display panel DP. The trenches TR may be defined in the barrier layer BAR3, and the openings OP may be defined in the support plate SP3. As the openings OP are connected to the outside through the trenches TR, air may flow smoothly into the openings OP. Since the air pressure inside the openings OP may correspondingly change even when external air pressure changes, occurrence of defects such as bubbles inside the display module DM3 and deformation of the display panel DP may be prevented or minimized. Accordingly, reliability of the display module DM3 and an electronic device (e.g., the display device DD of FIG. 1) manufactured by using the same may be improved.

The display device DD and the display modules DM1, DM2, and DM3 according to embodiments of the present disclosure may be applied to various electronic devices. An electronic device according to an embodiment of the present disclosure may be manufactured by using the above-described display module (or metal plate). An electronic device according to an embodiment may include the above-described display device and may further include a module or a device having another additional function besides the display device.

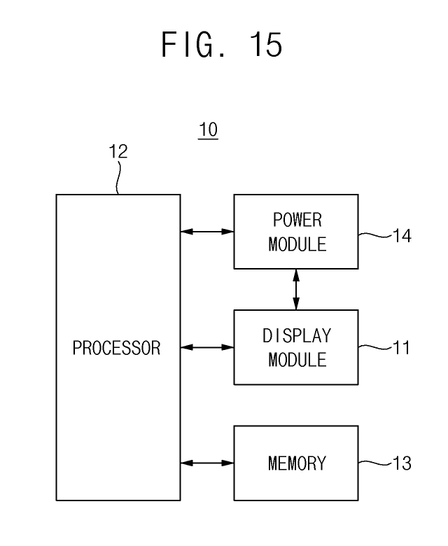

FIG. 15 is a block diagram illustrating an electronic device according to an embodiment.

Referring to FIG. 15, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may provide a control signal and an input image data to a control part of the display module 11.

In the memory 13, data information required for operations of the processor 12 or the display module 11 may be stored. When the processor 12 executes an application stored in the memory 13, the control signal and/or the input image data may be transmitted to the display module 11, and the display module 11 may process the received signals and output image information through a display screen.

The power module 14 may include a power supply module such as a power adapter or a battery device, and a power conversion module which converts power supplied by the power supply module to generate power required for operation of the electronic device 10.

At least one of the components of the electronic device 10 may be included in the display device according to an embodiment of the present disclosure described above. In addition, among individual modules functionally included in one module, some may be included in the display device, and others may be provided separately from the display device. For example, the display device may include the display module 11, and the processor 12, the memory 13, and the power module 14 may be provided as other devices within the electronic device 10 rather than within the display device.

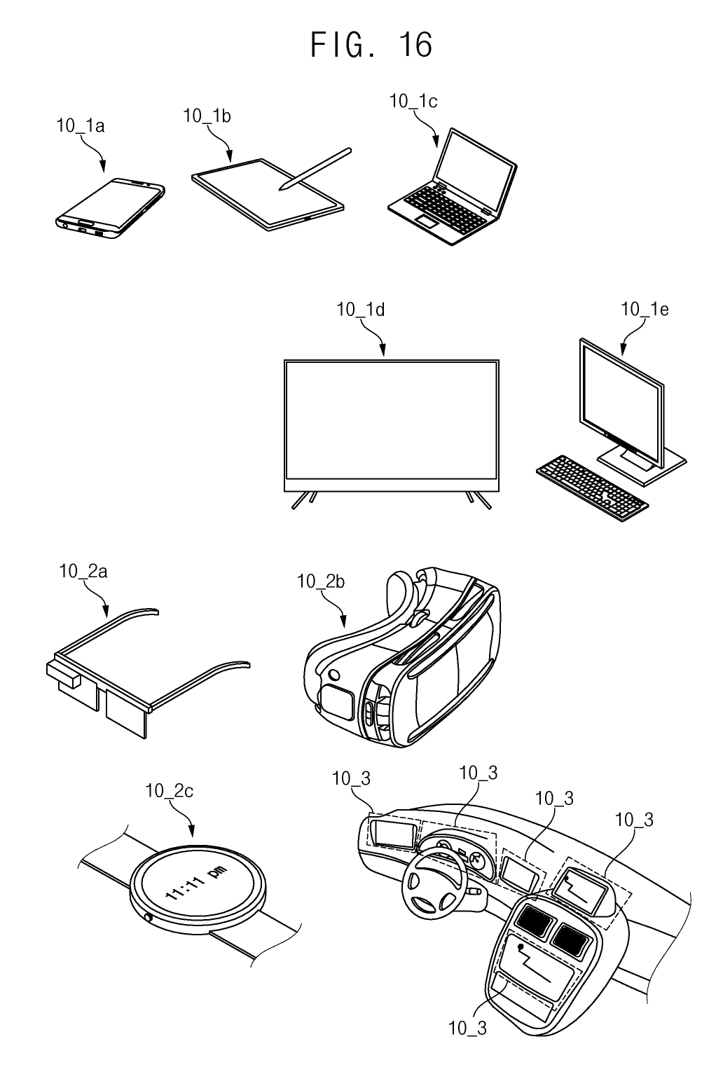

FIG. 16 is a schematic diagram illustrating electronic devices according to embodiments.

Referring to FIG. 16, various electronic devices to which the display device and the display module according to embodiments of the present disclosure are applied may include not only image display electronic devices such as a smartphone 10_1a, a tablet PC 10_1b, a laptop 10_1c, a TV 10_1d, and a desktop monitor 10_1e, but also wearable electronic devices including modules such as smart glasses 10_2a, a head-mounted display 10_2b, and a smart watch 10_2c, and vehicle electronic devices 10_3 including modules such as a center information display (CID) disposed on an instrument panel, a center fascia, or a dashboard of a vehicle, and a room mirror display.

The present disclosure may be applied to a display device and an electronic device including the same. For example, the present disclosure may be applied to high-resolution smartphones, mobile phones, smart pads, smart watches, tablet PCs, vehicle navigation systems, televisions, computer monitors, and laptops.

While the present disclosure has been described with reference to embodiments, it will be understood by those skilled in the art that various modifications and changes may be made without departing from the spirit and scope of the present disclosure as set forth in the following claims.

What is claimed is:

1. A display module comprising:
a display panel including a deformation area capable of sliding or bending and a non-deformation area adjacent to the deformation area, and including a plurality of pixels;
a support plate disposed under the display panel and defining a plurality of openings overlapping the deformation area and the non- deformation area in a plan view; and
a protective film disposed on the support plate and defining a plurality of trenches recessed from a first surface of the protective film, which faces the support plate, toward a second surface of the protective film, which is opposite the first surface, wherein each of the plurality of trenches overlaps at least one of the plurality of openings in the plan view.

2. The display module of claim 1, wherein each of the plurality of trenches is spatially connected to and overlaps at least one of the plurality of openings in the plan view.

3. The display module of claim 2, wherein each of the plurality of trenches extends in a first direction and each of the plurality of openings extends in a second direction intersecting the first direction.

4. The display module of claim 3, wherein the protective film includes a first protective film and a second protective film, and
the second protective film is disposed between the first protective film and the support plate.

5. The display module of claim 4, wherein the first protective film includes a first base layer and a first adhesive layer disposed on the first base layer, and
the second protective film includes a second base layer and a second adhesive layer disposed on the second base layer.

6. The display module of claim 4, wherein the first protective film and the second protective film include a same material.

7. The display module of claim 4, wherein the second protective film includes a plurality of patterns spaced apart from each other,
the plurality of patterns defines the plurality of trenches, and
the plurality of patterns and the plurality of trenches are alternately arranged along the second direction.

8. The display module of claim 4, wherein a first thickness of the first protective film and a second thickness of the second protective film are the same.

9. The display module of claim 1, wherein a first width of each of the plurality of patterns in a direction in which each of the plurality of openings extends is greater than or equal to a second width of each of the plurality of trenches in the direction.

10. The display module of claim 1, wherein the plurality of trenches overlaps the deformation area and the non-deformation area in the plan view.

11. The display module of claim 1, wherein the protective film is disposed under the support plate.

12. The display module of claim 1, wherein the protective film is disposed between the display panel and the support plate.

13. A metal plate comprising:
a support plate defining a plurality of openings across a whole surface thereof in a plan view and defining a plurality of trenches recessed from a first surface toward a second surface opposite the first surface, wherein each of the plurality of trenches is spatially connected to at least one of the plurality of openings; and
a protective film disposed on the support plate.

14. The metal plate of claim 13, wherein the support plate includes first patterns and second patterns, which are connected to each other, and
a thickness of each of the first patterns is different from a thickness of each of the second patterns.

15. The metal plate of claim 14, further comprising:
a barrier layer disposed on the support plate,
wherein the support plate is disposed between the protective film and the barrier layer,
the first patterns contact the barrier layer and the protective film, and
the second patterns contact the barrier layer, are spaced apart from the protective film, and define the plurality of trenches.

16. The metal plate of claim 14, wherein the first patterns are arranged in a first direction, and
the second patterns are arranged in the first direction.

17. The metal plate of claim 16, wherein the first patterns and the second patterns are alternately arranged along a second direction intersecting the first direction.

18. The metal plate of claim 13, wherein the plurality of trenches is defined across the whole surface of the support plate.

19. An electronic device comprising:
a display device including a plurality of pixels; and
a processor, which provides a control signal and an input image data to the display device,
wherein the display device includes:
a display panel including a deformation area capable of sliding or bending and a non-deformation area adjacent to the deformation area, and including a plurality of pixels; and
a support plate disposed under the display panel and defining a plurality of openings overlapping the deformation area and the non-deformation area in a plan view, and
wherein the electronic device is manufactured by removing a protective film from a display module including: the display panel, the support plate, and the protective film disposed on the support plate and defining a plurality of trenches recessed from a first surface of the protective film, which faces the support plate, toward a second surface of the protective film, which is opposite the first surface, and
wherein each of the plurality of trenches overlaps at least one of the plurality of openings in the plan view.
